(19) United States
(12) Patent Application Publication
(10) Pub. No.: US 2002/0009881 A1
(43) Pub. Date: Jan. 24, 2002

(54) Conductor member formation and pattern formation methods

(76) Inventor: Tomohiko Ezura, Tokyo (JP)

Correspondence Address: ROSENTHAL & OSHA L.L.P., Suite 4550, 700 Louisiana, Houston, TX, 77002, US

(21) Appl. No.: 09/903,478

(22) Filed: Jul. 11, 2001

(30) Foreign Application Priority Data
Jul. 11, 2000 (JP) 2000-210285

(51) Int. Cl. H01L 21/44

(52) U.S. Cl. 438/658

(57) ABSTRACT

A method for forming a fine conductor member with a high degree of precision is provided. A conductor member formation method having a process for forming a first film on a base material, a process for forming a second film on the first film, a process for forming a first opening part on the second film so that the second film will have a prescribed pattern, a process for removing a portion of the first film so that the second film will serve as a hood, a process for forming a conductor member on the base material using the first film and the second film as masks, and a process for removing the first film and the second film, is provided.

This patent application claims priority based on a Japanese patent application, 2000-210285 filed on Jul. 11, 2000, the contents of which are incorporated herein by reference.

### BACKGROUND OF THE INVENTION

1. Field of the Invention

The present invention relates to a conductor member formation method and a pattern formation method. In particular, the present invention relates to a conductor member formation method using a plurality of mask layers to form a fine conductor member.

2. Description of the Related Art

FIG. 1 shows an intermediate process of a conventional conductor member formation method. According to this method, in order to form a conductor member 14, a resist 12 is first coated on a base material 10. A prescribed pattern is then formed by exposing and developing the resist 12. Next, using the resist 12 as a mask, a conductor member 14 is deposited via sputtering or the like. The conductor member 14 deposited on the resist 12 is partially removed by gradually removing the resist 12 using a liquid developer so that the conductor member 14 will remain only on the prescribed region of the base material 10. As shown in FIG. 1(a), an opening 16 which extends in the direction of the exposure direction can be formed by controlling an exposure parameter when the resist 12 is exposed.

As miniaturization of semiconductor devices has progressed in recent years, an exposure system that uses an electron beam has started to be used in order to form conductor members such as electrodes and wires to be installed on semiconductor devices. In this exposure system, an electron beam resist is used. However, when an electron beam is irradiated onto an electron beam resist, the energy of the electron beam causes the top layer of the electron beam resist to melt down. As a result, as shown in FIG. 1(b), an opening part, which narrows down in the direction of the electron beam irradiation or is substantially vertically shaped, is formed. Therefore, forming an opening part which extends in width in the direction of the electron beam irradiation as shown in FIG. 1(a) is very difficult.

When a conductor member 14 is formed via sputtering or the like using a resist 12 for a mask which has an opening part that is substantially vertically shaped or narrows down in the direction of the electron beam irradiation, the portion of the conductor member 14 deposited on the base material 10 comes in contact with the portion of the conductor member 14 deposited on the resist 12 as shown in FIG. 1(b). In this case, it is very difficult to form a conductor member 14 having a prescribed shape on the base material 10 by removing the resist 12. Moreover, the thickness of the conductor member 14 to be formed on the base material 10 is restricted by the thickness of the resist 12. Since the thickness of the electron beam resist 12 needs to be made sufficiently small, it has been very difficult to form a thick conductor member 14.

### SUMMARY OF THE INVENTION

Therefore, it is an object of the present invention to provide conductor formation methods and pattern formation methods which overcome the above issues in the related art. This object is achieved by combinations described in the independent claims. The dependent claims define further advantageous and exemplary combinations of the present invention.

According to the first aspect of the present invention, a conductor member formation method having a process for forming a first film on a base material, a process for forming on the first film a second film which is etched more slowly than the first film by a prescribed etchant, a process for forming a first opening part on the second film so that the second film will have a prescribed pattern, a process for forming a hole part on the first film by removing a first portion of the first film beneath the bottom of the first opening part and a second portion of the first film which forms adjacent to the first portion of the first film using a prescribed etchant, a process for forming a hole part which penetrates through the first film, a process for forming a conductor member inside the hole part on a portion of the base material, and a process for removing the first film and the second film. In this case, a process for removing the first and second films after the conductor member has been formed in the hole part may be added.

Moreover, it is preferable that the process for forming the second film will include a process for coating an electron resist, which reacts to an irradiated electron beam, onto the first film, and the process for forming the first opening part include a process for exposing the electron beam resist and a process for developing the electron beam resist. It is further preferable that the process for forming the first film include a process of forming a film that reacts to an electron beam less than the electron beam resist.

Further, a process for removing a portion of the surface layer of the base material may be added. Moreover, the process of removing a portion of the surface layer of the base material may contain a process for removing a first portion of the surface layer of the base material which is beneath the bottom of the hole part, and a second portion of the surface layer of the base material which is adjacent to the first portion of the surface layer of the base material.

Moreover, the process for forming a hole part may contain a process for forming a second opening part on the first film by removing at least the first portion of the first film that lies beneath the bottom of the first opening part, a process for removing a portion of the surface layer of the base material, and a process for creating a hole part by removing a portion of the first film which is in the neighborhood of the second opening part. Moreover, the process for removing a portion of the surface layer of the base material may contain a process for removing a first portion of the surface layer of the base material which is beneath the bottom of the second opening part and a second portion of the surface layer of the base material which forms an adjacent region of the first portion of the surface layer.

Moreover, the process for forming a second opening part may contain a process for removing at least a portion of the first film beneath the bottom of the first opening part via an anisotropic etching.

According to the second aspect of the present invention, a pattern formation method having a process for forming a film on a base material, a process for forming an electron beam resist, which reacts to an irradiated electron beam, on the film, a process for forming an opening part on the electron beam resist by exposing and developing the electron beam resist so that the electron beam resist will have a prescribed pattern, and a process for forming a hole part on the film by removing a first portion of the film beneath the bottom of the opening part and a second portion of the film which is adjacent to the first portion of the film.

It should be noted here that the summary of the invention described above does not list all the characteristics of the present invention. Sub combinations of these characteristics are also included in the technical range of application of the present invention.

### BRIEF DESCRIPTION OF THE DRAWINGS

FIG. 1 shows an intermediate process of the conventional conductor member formation method.

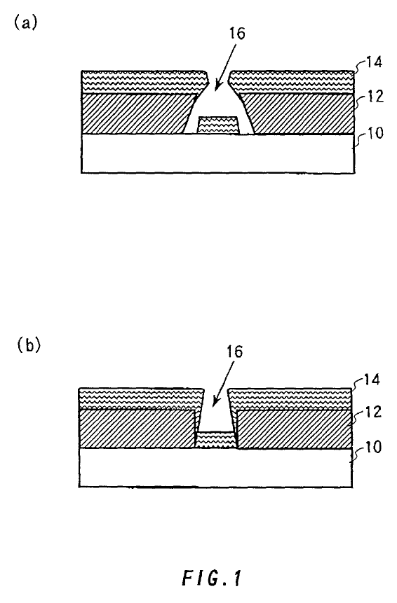

FIG. 2 shows a conductor member formation method according to an embodiment of the present invention.

FIG. 3 shows another embodiment of the conductor member formation method according to the present invention.

FIG. 4 shows yet another embodiment of the conductor member formation method according to the present invention.

### DETAILED DESCRIPTION OF THE INVENTION

In what follows, the present invention will be explained with embodiments of the present invention. However, the following embodiments do not restrict the scope of the invention described in the claims. Moreover, not all the combinations of the characteristics of the present invention described in the embodiments are essential to the problem solving means by the present invention.

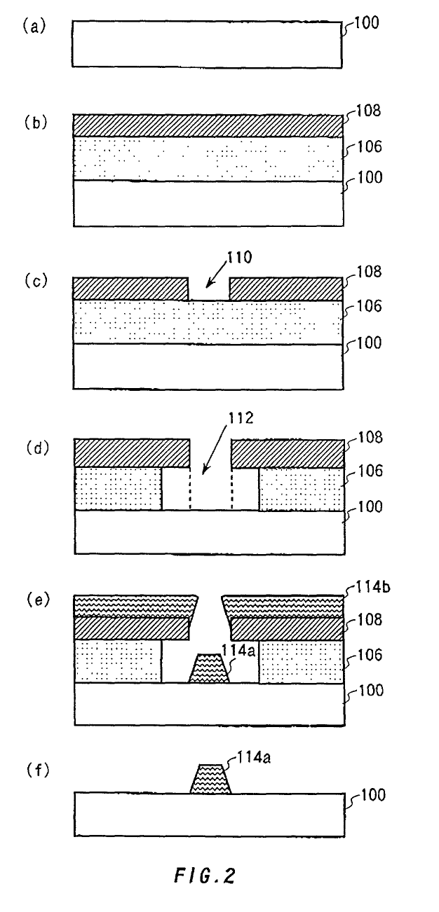

FIG. 2 shows a conductor member formation method according to an embodiment of the present invention. First, as shown in FIG. 2(a), a base material 100 is prepared.

FIG. 2(b) shows a process for forming a first film 106 and a process for forming a second film 108. It is desirable that the first film 106 be formed using a material that is hard to remove when a portion of the second film 108 is removed in the process of forming a first opening that is to be discussed later. To be specific, it is desirable that a material for forming the first film 106 be selected appropriately so that the first film 106 will be etched significantly more slowly than the second film 108 by the etchant to be used for removing the second film 108, such as a liquid developer, an etching solution, or an etching gas. Moreover, in the process of forming a hole part to be discussed later, it is desirable that an appropriate material for forming the first film 106 be selected 80 that the first film 106 will be etched significantly faster than the second film 106 by an etchant to be used for removing a portion of the first film 106, such as a liquid developer, an etching solution, or an etching gas. The first film 106 may be formed using a material having a degree of adhesion to the base material 100 higher than the degree of adhesion of the second film 108 to the first film 106. In the present embodiment, the first film 106 is formed using an organic material containing cyclopentanon (C₅H₈O). It is desirable that at least 90% of the organic material be constituted of cyclopentanon (C₅H₈O).

In the case the second film 108 is formed using a material such as a resist, which is photo-sensitive to a light source having a prescribed wavelength, it is desirable that a material for forming the first film 106 be suitably selected so that it has a lower photo-sensitivity to the light source than the material used for forming the second film 108. It is further desirable that a material for forming the first film 106 be suitably selected so that, when the second film 108 is developed using a liquid developer, the first film 106 will be removed by the liquid developer at a rate significantly slower than the rate at which the region on which the first opening part is to be formed is removed, where the region refers to either the portion of the second film 108 exposed to the light source or the remaining portion of the second film 108 not exposed to the light source.

In the present embodiment, the first film 106 is formed in the following process using a material that is significantly less prone to react to an electron beam, i.e., to a lower degree, than the material used to form the second film 108 and is also soluble to a prescribed liquid developer. First, a precursor, which is a material for forming the first film 106, is coated on the base material 100 via spin-coat method. The precursor is deposited on the base material 100, for example, by coating the precursor onto the base material 100 while rotating the base material 100 at a rate between 1000 and 3000 rotations per minute for a length of time between 60 seconds and 180 seconds. In this case, it is preferable that the first film 106 (precursor) be deposited to a thickness between 50 nm and 300 nm (nanometer). It is further preferable that the first film 106 (precursor) be deposited to a thickness between 100 nm and 200 nm. Next, by heat-processing (baking) the precursor for 5 minutes at the temperature of 160° C. using a hot plate, the first film 106 is formed on the base material 100.

The second film 108 is formed on the first film 106. In the present embodiment, the second film 108 is formed in the following process using an electron beam resist which reacts to an irradiated electron beam. First, an electron beam resist is coated on the first film 106 via spin-coat method. Next, the electron beam resist is baked for 3 minutes at the temperature of 120° C. using a hot plate to form a second film 108 on the first film 106. The second film 108 is formed to a thickness, for example, between 200 nm and 1000 nm. In the case the first film 106 is also formed using a resist, the first film 106 may be formed by coating the resist onto the base material 100 several times.

The first film 106 and/or the second film 108 may be formed, for example, using an inorganic material such as silicon oxide, silicon nitride, or the like. Moreover, the first film 106 and/or the second film 108 may be formed using a semiconductor, a metallic material, or the like. In this case also, it is desirable that the first film 106 be formed using a material that is etched faster than the second film 108 by a prescribed etchant when forming a hole part in the first film 106.

FIG. 2(c) shows a process for forming the first opening part 110. The first opening part 110 is formed by removing a portion of the second film 108. For example, in the case the second film 108 has photo-sensitivity, the first opening part 110 maybe formed by exposing and developing the second film 108. In this case, it is desirable that the diameter and/or width of the first opening part 110 be between 50 nm and 250 nm. In the present embodiment, the first opening part 110 is formed by the following process. First, using an electron beam exposure apparatus, an electron beam is irradiated onto a prescribed region of the second film 108 which is an electron beam resist. In this case, in the process to be discussed later, when the region on which a conductor member is to be formed on the base material 100 is narrower than the region on which the conductor member is not to be formed, it is desirable that the electron beam resist forming the second film 108 be a positive type. By forming the second film 108 using a positive type electron beam resist, the length of time for exposing the electron beam can be shortened by a significant degree.

Next, the first opening part 110 is formed on the second film 108 so that the second film 108 will have a prescribed pattern by removing the region of the electron beam resist on which an electron beam has been irradiated. In this case, the first opening part 110 maybe formed substantially vertical to the plane on which the first film 106 contacts the base material 100. Alternatively, the first opening part 110 may be formed so as to extend in the direction from the second film 108 to the base material 100.

FIG. 2(d) shows a process for forming the hole part 112. It is desirable that the hole part 112 be formed by removing a first portion of the first film 106 which lies at the bottom of the first opening part 110 and a second portion of the first film 106 which constitutes an adjacent neighborhood of the first portion of the first film 106. To be specific, it is desirable that the hole part 112 be formed by removing a portion of the first film 106 in such a manner that the second film 108 forms a hood.

It is desirable that the hole part 112 be formed by a removing method which selectively removes the first film 106. To be specific, the hole part 112 may he formed using an etchant which etches the second film 108 more slowly than the first film 106. In the present embodiment, the hole part 112 is formed using a liquid developer by removing a first portion of the first film 106 that lies at the bottom of the first opening part 110 and a second portion of the first film 106 which constitutes an adjacent neighborhood of the first portion of the first film 106. It is preferable that the liquid developer be able to develop (remove) the first film 106 selectively. For example, a weak alkaline liquid developer may be used.

In the process of forming the hole part 112, the size of the hole part 112 can be controlled by controlling the length of time for etching the first film 106. Alternatively, the size of the hole part 112 may be controlled by controlling the concentration of the etchant.

FIG. 2(e) shows a process for forming a conductor member 114. The conductor member 114 is formed by depositing a conductive material. In the present embodiment, the conductor member 114 is formed by vapor-depositing a conductive material. More specifically, a conductor member 114a is formed when the conductive material passes through the opening part 110 and the hole part 112 and reaches the base material 100, and the conductive material deposited on the second film 108 forms a conductor member 114b. In this case, it is desirable that the conductor member 114a be formed to a thickness between 100 nm and 500 nm.

In the process of forming the conductor member 114, the second film 108 and the first film 106 serve as hoods. Therefore, the conductor member 114 is unlikely to adhere to the interior wall of the hole part 112 which constitutes the side wall of the first film 106. As a consequence, the conductor member 114a can be formed in such a manner that the conductor member 114a will not come in contact with the conductor member 114b. Moreover, even in the case the film thickness of the conductor member 114 is large, by increasing the thickness of the first film 116, the conductor member 114a can be formed in such a manner that the conductor member 114a will not come in contact with the conductor member 114b.

FIG. 2(f) shows a process for removing the first film 106 and the second film 108. By removing the first film 106 and the second film 108, the conductor member 114b is removed (lifted off). As a result, only the conductor member 114a remains on the base material 100. It is desirable that the first film 106 and the second film 108 be removed using an etchant capable of dissolving both the first film 106 and the second film 108. In the present embodiment, the first film 106 and the second film 108 are removed using a liquid developer capable of dissolving both the first film 106 and the second film 108. In another embodiment, the conductor member 114b may be removed by removing only the second film 108. In this case, an insulating film or a metal film may be further deposited on the first film 106. Alternatively, the conductor member 114b may be used as another wire without removing the first film 106 and the second film 108.

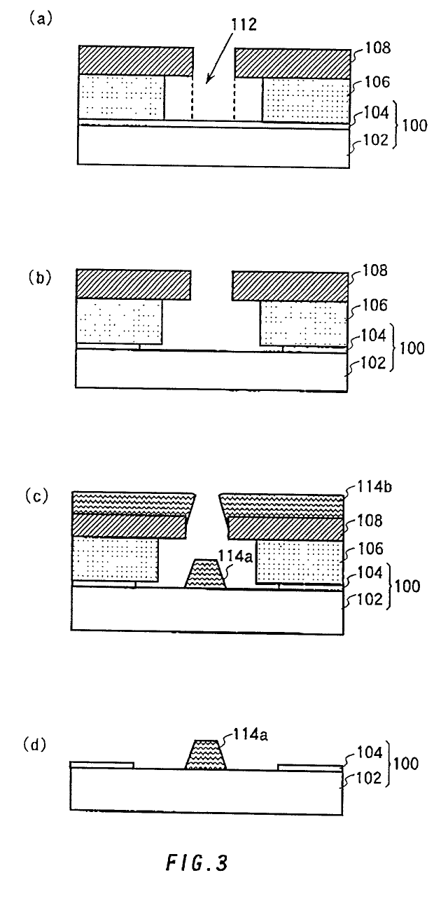

FIG. 3 shows another embodiment of the present invention. FIG. 3(a) shows a state in which a hole part 112 has been formed via the process that has been explained with reference to FIGS. 2(a) through (d). In the present embodiment, the base material 100 has a first layer 102 and a second layer 104.

FIG. 3(b) shows a process for removing a portion of the surface layer of the base material 100. It is desirable that a portion of the surface layer of the base material 100 be removed using the first film 106 as a mask. In the case the base material 100 has several layers, the layer adjacent to the first film 106 may be removed. In the present embodiment, a portion of the second layer 104, which is part of the surface layer of the base material 100, is removed via wet etching. To be specific, a first portion of the second layer 104, which is at the bottom of the hole part 112 and is part of the surface layer of the base material 100, and a second portion of the second layer 104 which constitutes an adjacent neighborhood of the first portion of the second layer 104 are removed via wet etching.

In the process of forming a hole part 112, a first portion of the first film 106, which lies directly beneath the bottom of the opening part 110 (note FIG. 2(c)), and a second portion of the first film 106, which constitutes an adjacent neighborhood of the first portion of the first film 106, are removed. As shown in FIG. 2(c) and FIGS. 3(a) and (b), in the process of removing a portion of the second layer 104 which forms the surface layer of the base material 100, the range of removal of the second layer 104 can be controlled by controlling the amount of removal of the second portion of the first film 106 in the process of forming a hole part 112. Moreover, in the process of removing a portion of the second layer 104 (the surface layer) of the base material 100, by controlling the length of time the portion of the second layer 104 is etched, the range of removal of the second layer 104 can be controlled.

FIG. 3(c) shows a process for forming a conductor member 114. A conductor member 114 is formed by depositing a conductive material. In the present embodiment, a conductor member 114 is formed by vapor-depositing a conductive material. More specifically, a conductor member 114a is formed when the conductive material passes through the opening part 110 and the hole part 112 and reaches the first layer 102 of the base material 100, and the conductive material deposited on the second film 108 forms a conductor member 114b.

FIG. 3(d) shows a process for removing the first film 106 and the second film 108. By removing the first film 106 and the second film 108, the conductor member 114b is removed (lifted off). As a result, only the conductor member 114a remains on the first layer 102 of the base material 100. It is desirable that the first film 106 and the second film 108 be removed using an etchant capable of dissolving both the first film 106 and the second film 108. In the present embodiment, the first film 106 and the second film 108 are removed using a liquid developer capable of dissolving both the first film 106 and the second film 108.

A high electron mobility transistor (HEMT) having a first layer 102, which serves as a carrier supply layer, and a second layer 104, which serves as a cap layer of the carrier supply first layer 102, may be used for the base material 100. A gate electrode formed on the HEMT may constitute the conductor member 114a. In this case, it is desirable that a source electrode and/or drain electrode be formed on the top layer of the first layer 102 or second layer 104.

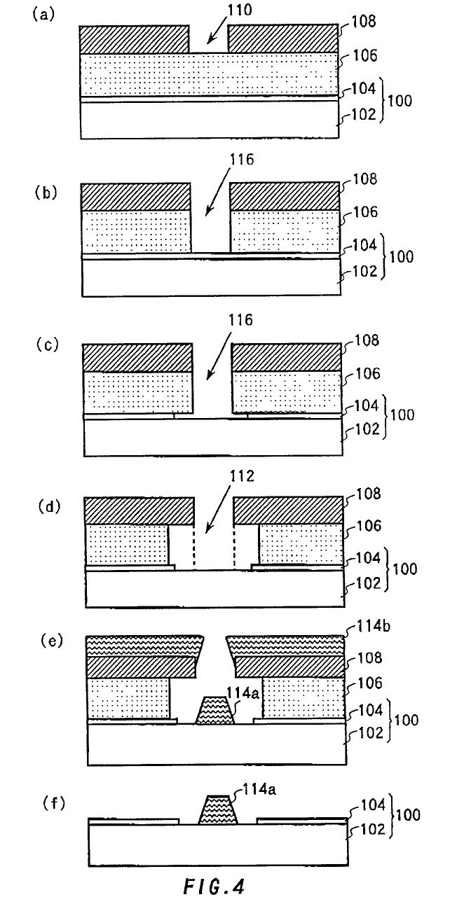

FIG. 4 shows another embodiment of the conductor member formation method of the present invention. FIG. 4(a) shows a state in which a first opening part 110 has been formed through the processes that have been explained with reference to FIGS. 2(a) through (c). In the present embodiment, the base material 100 has a first layer 102 and a second layer 104.

FIG. 4(b) shows a process for forming a second opening part 116. It is desirable that the second opening part 116 be formed by removing at least the portion of the first layer 106 that lies at the bottom of the first opening part 110. Moreover, it is desirable that the second opening part 116 be formed via an anisotropic etching. In the present embodiment, the second opening part 116 is formed via an anisotropic etching by removing at least the portion of the first layer 106 that lies at the bottom of the first opening part 110. It is desirable that the width of the second opening part 116 be less than or substantially equal to the width of the first opening part 110. Alternatively, the second opening part 116 may be formed via an anisotropic etching in such a manner that its width will decrease in the direction of the etching process.

FIG. 4(c) shows a process for removing a portion of the surface layer of the base material 100. It is desirable to remove a portion of the surface layer of the base material 100 using the first film 106 as a mask. In the case the base material 100 has several layers, the layer adjacent to the first film 106 may be removed. In the present embodiment, a portion of the second layer 104, which constitutes the surface layer of the base material 100, is removed via wet etching. To be specific, the first portion of the second layer 104 beneath the bottom of the second opening part 116, which is part of the surface layer of the base material 100, and a second portion of the first film 106, which is an adjacent neighborhood of the above-mentioned first portion of the first film 106, are removed via wet etching. In this case, it is preferable to use an etchant which etches the second layer 104 sufficiently faster than the first layer 102.

In the process of forming the second opening part 116, the second opening part 116 is created by removing a portion of the first film 106 via an anisotropic etching. As a result, in the process of removing a portion of the surface layer of the base material 100, the portion of the second layer 104, which is to be removed, can be made narrow. Moreover, in FIG. 4(c), the region of the second layer 104 damaged by the anisotropic etching can be removed.

FIG. 4(d) shows a process for forming a hole part 112. It is desirable that the hole part 112 be formed by removing a side wall portion of the first film 106 which surrounds the second opening part 116. More specifically, it is desirable to form the hole part 112 by removing a side wall portion of the first film 106 in such a manner that the second film 108 serves as a hood over the hole part 112.

It is desirable that the hole part 112 be formed via an etching method by which the first film 106 can be selectively removed. To be specific, the hole part 112 may be formed using an etchant which etches the first film 106 sufficiently faster than the second film 108. In the present embodiment, the hole part 112 is formed using a liquid developer by first removing a first portion of the first film 106 which lies beneath the bottom of the first opening part 110 (note FIG. 2(b)) and then further removing a second portion of first film 106 adjacent to the above-mentioned first portion of the first film 106 (note FIG. 2(d)). In this case, it is preferable to use a liquid developer that is able to selectively develop (remove) the first film 106. For example, a weakly alkaline liquid developer may be used.

FIG. 4(e) shows a process for forming a conductor member 114. The conductor member 114 is formed by depositing a conductive material. In the present embodiment, the conductor member 114 is deposited by vapor-depositing a conductive material. More specifically, a conductor member 114a is formed when the conductive material passes through the opening part 110 and the hole part 112 and reaches the first layer 102 of the base material 100, and the conductive material deposited on the second film 108 forms a conductor member 114b.

FIG. 4(f) shows a process for removing the first film 106 and the second film 108. By removing the first film 106 and the second film 108, the conductor member 114b is removed (lifted off). As a result, only the conductor member 114a remains on the first layer 102 of the base material 100. It is preferable that the first film 106 and the second film 108 be removed using an etchant capable of dissolving both the first film 106 and the second film 108. In the present embodiment, the first film 106 and the second film 108 are removed using a liquid developer capable of dissolving both the first film 106 and the second film 108.

In the present embodiment, for example, a HEMT having a first layer 102, which serves as a carrier supply layer, and a second layer 104, which serves as a cap layer of the carrier supply first layer 102 may be used for the base material 100. A gate electrode formed on the HEMT may constitute the conductor member 114a. In this case, it is desirable that a source electrode and/or drain electrode be formed on the upper layer of the first layer 102 or second layer 104. Moreover, the base material 100 maybe a portion of a photo conductor. In this case, it is preferable that the conductor member 114a be formed in the shape of a comb on the base material 100.

In the process of forming a second opening part 116, the second opening part 116 is formed by removing a portion of the first film 106 via an anisotrpic etching. As a result, in the process of removing a portion of the base material 100, the area of the region of the second layer 104 to be removed, which is the region of the surface layer of the base material 100 to be removed, can be controlled. By controlling the area of the region of the second layer 104 to be removed, the distance between the drain and the source can be controlled. As a consequence, characteristics of the HEMT such as the gate voltage and the drain current can be controlled. Moreover, in the case a device having a conductor member such as a HEMT is installed on a wafer, the degree of formation accuracy of the conductor member within the wafer can be significantly improved.

As explained above, according to the present invention, a fine pattern can be formed.

Although the present invention has been described by way of exemplary embodiments, it should be understood that many changes and substitutions may be made by those skilled in the art without departing from the spirit and the scope of the present invention which is defined only by the appended claims.

What is claimed is:

1. A conductor member formation method, comprising the steps of:
forming a first film on a base material;
forming on said first film a second film which is etched more slowly than said first film by a prescribed etchant;
forming a first opening part on said second film so that said second film has a prescribed pattern;
forming a hole part on said first film by removing a first portion of said first film which is located beneath said first opening part and a second portion of said first film, which is adjacent to said first portion of said first film, using said prescribed etchant; and
forming in said hole part a conductor member on a region of said base material.

2. A conductor member formation method as claimed in claim 1, wherein said step of forming a second film has a step of coating an electron beam resist, which reacts to an irradiated electron beam, on said first film,
and wherein said step of forming a first opening part has the steps of:
exposing said electron beam resist; and
developing said electron beam resist.

3. A conductor member formation method as claimed in claim 2, wherein said step of forming a first film has the step of forming a film which reacts less to said electron beam than said electron beam resist.

4. A conductor member formation method as claimed in claim 1, further comprising the step of removing a portion of a surface layer of said base material.

5. A conductor member formation method as claimed in claim 4, wherein said step of removing a portion of said surface layer of said base material has the step of removing a first portion of said surface layer of said base material that is located beneath said hole part and a second portion of said surface layer of said base material that is adjacent to said first portion of said surface layer of said base material.

6. A conductor member formation method as claimed in claim 1, wherein said step of forming a hole part has the steps of:
forming a second opening part on said first film by removing at least a first portion of said first film which is located beneath said first opening part;
removing a portion of a surface layer of said base material; and
forming said hole part by removing a second portion of said first film which is adjacent to said first portion of said first film.

7. A conductor member formation method as claimed in claim 6, wherein said step of removing a portion of said surface layer of said base material includes the step of removing a first portion of said surface layer of said base material which is located beneath said second opening part and a second portion of said surface layer of said base material which is adjacent to said first portion of said surface layer of said base material.

8. A conductor member formation method as claimed in claim 6, wherein said step of forming a second opening part includes the step of removing at least a portion of said first film which is located beneath said first opening part using an anisotropic etching.

9. A pattern formation method comprising the steps of:
forming a film on a base material;
forming on said film an electron beam resist which reacts to an irradiated electron beam;
forming an opening part on said electron beam resist by exposing and developing said electron beam resist so that said electron beam resist has a prescribed pattern; and
forming a hole part on said film by removing a first portion of said film which is located beneath said opening part and a second portion of said film which is adjacent to said first portion of said film.
